(19) United States
(12) Patent Application Publication
(10) Pub. No.: US 2023/0265227 A1
(43) Pub. Date: Aug. 24, 2023

(54) VINYL-BASED POLYMER, CURABLE COMPOSITION, AND CURED PRODUCT

(71) Applicant: Mitsubishi Chemical Corporation, Tokyo (JP)

(72) Inventors: Mayu YAMAGUCHI, Tokyo (JP); Takafumi ASAI, Tokyo (JP); Akira SATO, Tokyo (JP)

(73) Assignee: Mitsubishi Chemical Corporation, Tokyo (JP)

(21) Appl. No.: 18/189,567

(22) Filed: Mar. 24, 2023

Related U.S. Application Data
(63) Continuation of application No. PCT/JP2021/048536, filed on Dec. 27, 2021.

(30) Foreign Application Priority Data
Jan. 8, 2021 (JP) 2021-002164

(51) Int. Cl. C08F 212/08; C08F 220/14; C08F 220/06; C08F 2/38; C08F 2/18

(52) U.S. Cl. CPC C08F 212/08; C08F 2/18; C08F 2/38; C08F 220/06; C08F 220/14; C08F 2810/40

(57) ABSTRACT

Provided is a low-odor polymer which is soluble in a solvent and with which a work environment load can be reduced. In addition, provided are a curable composition using the polymer and a cured product of the curable composition. The vinyl-based polymer of the present invention comprises a terminal structure derived from one or more of 3- to 20-mer of a (meth)acrylic monomer, wherein an acid value is 35 to 300 mgKOH/g.

### TECHNICAL FIELD

The present invention relates to a vinyl-based polymer suitable for a photosensitive resin composition which is useful as a binder for inks or resists, a curable composition, and a cured product thereof.

This application is a continuation application of International Application No. PCT/JP2021/048536, filed Dec. 27, 2021, which claims the benefit of priority of the prior Japanese Patent Application No. 2021-002164, filed Jan. 8, 2021, the contents of which are incorporated herein by reference.

### BACKGROUND ART

A polymer containing a vinyl aromatic compound and methacrylic acid is industrially useful including for inks or resists, and has been widely used as a binder for dry film resists.

In order to impart, to the polymer containing a vinyl aromatic compound and methacrylic acid, suitable viscosity, water resistance, and alkaline water solubility for various uses such as inks and resists, it is necessary to control an appropriate formulation and an appropriate molecular weight.

Patent Document 1 discloses a suspension polymerization method in which a molecular weight of a polymer is controlled by using n-dodecyl mercaptan or α-methylstyrene dimer as a chain transfer agent. The method of Patent Document 1 is an excellent polymerization method in terms of obtaining polymer particles with favorable handleability, but since the n-dodecyl mercaptan is used, solubility in a solvent or alkaline water is not favorable. In addition, since there is an odor derived from the n-dodecyl mercaptan, there is room for improvement in that workability is not favorable and work environment load is large.

Patent Document 2 discloses a terminal unsaturated methacrylic acid ester n-mer as a chain transfer agent, which is capable of more efficiently controlling a molecular weight of a polymer or a copolymer to be produced; and a polymerization method using the same. In the method of Patent Document 2, since a chain transfer agent of an alkyl mercaptan is not used, reduction of the odor can be achieved. However, since the polymer does not have an acid group, solubility of the polymer in alkaline water is poor, resulting in unfavorable solvent solubility.

Patent Document 3 discloses a method for producing an addition polymer having a polymerizable olefinic terminal group. Since the polymer polymerized using the chain transfer agent produced by the method of Patent Document 3 does not have an acid group, solubility of the polymer in alkaline water is not favorable, and there is room for improvement in terms of solvent solubility.

### CITATION LIST

### Patent Documents

### [Patent Document 1]

Japanese Unexamined Patent Application, First Publication No. H7-102004

### [Patent Document 2]

Japanese Unexamined Patent Application, First Publication No. 2006-176587

### [Patent Document 3]

Published Japanese Translation No. 2000-514845 of the PCT International Publication

### SUMMARY OF INVENTION

### Technical Problem

An object of the present invention is to provide a low-odor polymer which can be used in a curable composition and a cured product thereof and is soluble in a solvent, with which a work environment load can be reduced.

### Solution to Problem

The gist of the present invention is the following [1] to [12].

[1] A vinyl-based polymer comprising a terminal structure derived from one or more of 3- to 20-mer of a (meth)acrylic monomer, wherein an acid value is 35 to 300 mgKOH/g.

The vinyl-based polymer according to [1], wherein the terminal structure is a terminal structure derived from a chain transfer agent.

The vinyl-based polymer according to [1] or [2], further comprising a structural unit derived from two or more of vinyl-based monomers.

The vinyl-based polymer according to [3], wherein one or more of the vinyl-based monomers is a vinyl-based monomer having an acid group.

The vinyl-based polymer according to [3] or [4], wherein one or more of the vinyl-based monomers is a vinyl-based monomer having an aromatic ring.

The vinyl-based polymer according to any one of [3] to [5], wherein one or more of the vinyl-based monomers is a (meth)acrylic monomer.

The vinyl-based polymer according to [6], wherein the (meth)acrylic monomer in the vinyl-based monomers is (meth)acrylic acid alkyl ester, and an alkyl group of an ester structure in the (meth)acrylic acid alkyl ester has 1 to 18 carbon atoms.

The vinyl-based polymer according to any one of [1] to [7], wherein a weight-average molecular weight is 5,000 to 1,000,000.

The vinyl-based polymer according to any one of [1] to [8], wherein the vinyl-based polymer is particulate, and a mass-average particle size of the particulate vinyl-based polymer is 20 to 2,000 µm.

A curable composition comprising the vinyl-based polymer according to any one of [1] to [9] and a compound having a polymerizable double bond.

The curable composition according to Claim 10, further comprising one or more of 3- to 20-mer of a (meth)acrylic monomer.

A cured product of the curable composition according to [10] or [11].

### Advantageous Effects of Invention

According to the present invention, it is possible to provide a low-odor polymer which can be used in a curable composition and a cured product thereof and is soluble in a solvent, with which a work environment load can be reduced.

### DESCRIPTION OF EMBODIMENTS

### Vinyl-Based Polymer

The vinyl-based polymer according to the present invention comprises, as a terminal structure of the polymer, a structure derived from one or more of 3- to 20-mer (trimer to icosamer) of a (meth)acrylic monomer, wherein an acid value is 35 to 300 mgKOH/g.

In the present invention, “(meth)acrylic” is a generic term for acrylic and methacrylic.

The vinyl-based polymer according to the present invention comprises, as a terminal structure of the polymer, one or more of 3- to 20-mer of a (meth)acrylic monomer. The terminal structure which is the 3- to 20-mer of a (meth)acrylic monomer is preferably 3- to 10-mer (decamer) of a (meth)acrylic monomer, and more preferably 3-to 5-mer (pentamer) of a (meth)acrylic monomer.

The terminal structure is preferably a terminal structure derived from a chain transfer agent. The terminal structure preferably further has a polymerizable double bond.

When the terminal structure of the polymer is a terminal structure derived from a chain transfer agent, solubility in a solvent is improved. In addition, when the terminal structure of the polymer has a polymerizable double bond, curability of the curable composition containing the vinyl-based polymer is improved, which is preferable. When the terminal structure of the polymer is a terminal structure derived from a chain transfer agent and the terminal structure of the polymer has a polymerizable double bond, the solubility of the polymer to a solvent is improved, and the curability of the curable composition containing the vinyl-based polymer is improved, which are more preferable.

As the (meth)acrylic monomer in the 3- to 20-mer of a (meth)acrylic monomer, for example, acrylic acid esters such as methyl acrylate, ethyl acrylate, n-butyl acrylate, i-butyl acrylate, t-butyl acrylate, 2-ethylhexyl acrylate, lauryl acrylate, dodecyl acrylate, stearyl acrylate, glycidyl acrylate, 2-hydroxyethyl acrylate, 2-hydroxypropyl acrylate, 2-methoxyethyl acrylate, and 2-ethoxyethyl acrylate;
methacrylic acid esters such as methyl methacrylate, ethyl methacrylate, n-butyl methacrylate, i-butyl methacrylate, t-butyl methacrylate, 2-ethylhexyl methacrylate, cyclohexyl methacrylate, lauryl methacrylate, dodecyl methacrylate, stearyl methacrylate, behenyl methacrylate, isobornyl methacrylate, phenyl methacrylate, benzyl methacrylate, glycidyl methacrylate, 2-hydroxyethyl methacrylate, 2-hydroxypropyl methacrylate, 2-methoxyethyl methacrylate, 2-ethoxyethyl methacrylate, phenoxyethyl methacrylate, 2-methacryloyloxyethyl hexahydrophthalate, and 2-methacryloyloxyethyl phthalate;
polymerizable amides such as acrylamide and methacrylamide; and
dialkylaminoethyl (meth)acrylates such as dimethylaminoethyl acrylate, diethylaminoethyl acrylate, dimethylaminoethyl methacrylate, and diethylaminoethyl methacrylate
are exemplary examples.

From the viewpoint of miscibility with monomer during the polymerization, acrylic acid esters or methacrylic acid esters are preferable; and from the viewpoint that a resin to be obtained has improved solubility in alkaline water and solvent solubility, methyl acrylate, ethyl acrylate, n-butyl acrylate, i-butyl acrylate, t-butyl acrylate, 2-ethylhexyl acrylate, cyclohexyl acrylate, phenyl acrylate, methyl methacrylate, ethyl methacrylate, n-butyl methacrylate, i-butyl methacrylate, t-butyl methacrylate, 2-ethylhexyl methacrylate, cyclohexyl methacrylate, or phenyl methacrylate is more preferable, and methyl methacrylate, ethyl methacrylate, or phenyl methacrylate is still more preferable.

These may be used alone or in combination of two or more thereof.

The terminal structure derived from a chain transfer agent refers to a chemical structural moiety derived from a chain transfer agent, which is used to control a molecular weight of various polymers or copolymers produced from a polymerizable monomer or a mixture thereof.

It is preferable that the vinyl-based polymer according to the present invention further comprises a structural unit derived from derived from two or more of vinyl-based monomers, in addition to the terminal structure.

As the vinyl-based monomer, maleimides such as N-phenylmaleimide and N-cyclohexylmaleimide;
monobasic acids such as acrylic acid, methacrylic acid, and crotonic acid;
dibasic acids such as fumaric acid, maleic acid, and itaconic acid, and partial esters of these dibasic acids;
vinyl compounds having a sulfonic acid group, such as vinylsulfonic acid and 2-acrylamido-2-methylpropanesulfonic acid; and
vinyl compounds having an aromatic ring, such as styrene, o-methylstyrene, m-methylstyrene, p-methylstyrene, α-methylstyrene, o-methoxystyrene, m-methoxystyrene, p-methoxystyrene, p-t-butylstyrene, p-t-butoxystyrene, l-vinylnaphthalene, 2-vinylnaphthalene, phenyl acrylate, benzyl acrylate, and phenoxyethyl acrylate
are exemplary examples.

From the viewpoint of improving the solubility of the polymer in alkaline water, it is preferable that one or more of the vinyl-based monomers is a vinyl-based monomer having an acid group.

As the vinyl-based monomer having an acid group, for example, monobasic acids such as acrylic acid, methacrylic acid, and crotonic acid;
dibasic acids such as fumaric acid, maleic acid, and itaconic acid, and partial esters of these dibasic acids; and
vinyl compounds having a sulfonic acid group, such as vinylsulfonic acid and 2-acrylamido-2-methylpropanesulfonic acid
are exemplary examples.

These may be used alone or in combination of two or more thereof.

From the viewpoint of improving the solvent solubility of the polymer, it is preferable that one or more of the vinyl-based monomers is a vinyl-based monomer having an aromatic ring.

As the vinyl-based monomer having an aromatic ring, for example, styrene, o-methylstyrene, m-methylstyrene, p-methylstyrene, α-methylstyrene, o-methoxystyrene, m-methoxystyrene, p-methoxystyrene, p-t-butylstyrene, p-t-butoxystyrene, l-vinylnaphthalene, 2-vinylnaphthalene, phenyl acrylate, benzyl methacrylate, benzyl acrylate, phenoxyethyl methacrylate, and phenoxyethyl acrylate, are exemplary examples. From the viewpoint of excellent solubility of the obtained vinyl-based polymer in a solvent or from the viewpoint of ease of availability, styrene, p-methylstyrene, p-methoxystyrene, or p-t-butylstyrene is preferable.

These may be used alone or in combination of two or more thereof.

The vinyl-based polymer according to the present invention may further have one or more of structural units derived from other monomers having a polymerizable double bond, in addition to the structural unit derived from a vinyl-based monomer having an acid group and the structural unit derived from a vinyl-based monomer having an aromatic ring.

The other monomers having a polymerizable double bond are not particularly limited as long as they are copolymerizable with the vinyl-based monomer having an acid group and the vinyl-based monomer having an aromatic ring.

As the other monomers having a polymerizable double bond, for example, acrylic acid esters such as methyl acrylate, ethyl acrylate, n-butyl acrylate, i-butyl acrylate, t-butyl acrylate, 2-ethylhexyl acrylate, lauryl acrylate, dodecyl acrylate, stearyl acrylate, glycidyl acrylate, 2-hydroxyethyl acrylate, 2-hydroxypropyl acrylate, 2-methoxyethyl acrylate, and 2-ethoxyethyl acrylate;
methacrylic acid esters such as methyl methacrylate, ethyl methacrylate, n-butyl methacrylate, i-butyl methacrylate, t-butyl methacrylate, 2-ethylhexyl methacrylate, cyclohexyl methacrylate, lauryl methacrylate, dodecyl methacrylate, stearyl methacrylate, behenyl methacrylate, isobornyl methacrylate, phenyl methacrylate, glycidyl methacrylate, 2-hydroxyethyl methacrylate, 2-hydroxypropyl methacrylate, 2-methoxyethyl methacrylate, 2-ethoxyethyl methacrylate, 2-methacryloyloxyethyl hexahydrophthalate, and 2-methacryloyloxyethyl phthalate;
polymerizable amides such as acrylamide and methacrylamide; and
dialkylaminoethyl (meth)acrylates such as dimethylaminoethyl acrylate, diethylaminoethyl acrylate, dimethylaminoethyl methacrylate, and diethylaminoethyl methacrylate, are exemplary examples.

These may be used alone or in combination of two or more thereof.

In the vinyl-based polymer according to the present invention, from the viewpoint of imparting hardness and flexibility to a cured product of the curable composition containing the vinyl-based polymer, it is preferable that one or more of the vinyl-based monomers is a (meth)acrylic monomer.

As the (meth)acrylic monomer, from the viewpoint of imparting hardness and flexibility to the cured product of the curable composition containing the vinyl-based polymer, (meth)acrylic acid alkyl ester is preferable, (meth)acrylic acid alkyl ester in which an alkyl group of an ester structure in the (meth)acrylic acid alkyl ester has 1 to 18 carbon atoms is more preferable, and ethyl acrylate, n-butyl acrylate, 2-ethylhexyl acrylate, methyl methacrylate, n-butyl methacrylate, or 2-ethylhexyl methacrylate is still more preferable.

In a case where the vinyl-based polymer according to the present invention has a structural unit derived from a vinyl-based monomer having an acid group, a mass proportion of the structural unit derived from a vinyl-based monomer having an acid group to structural units derived from all monomers of the vinyl-based polymer is preferably 5% to 60%, more preferably 10% to 45%, and still more preferably 15% to 40%. In a case of being the above-described lower limit value or more, the solubility of the curable composition containing the vinyl-based polymer in alkaline water is excellent. In a case of being the above-described upper limit value or less, the solubility in a solvent is excellent.

In a case where the vinyl-based polymer according to the present invention has a structural unit derived from a vinyl-based monomer having an aromatic ring, a mass proportion of the structural unit derived from a vinyl-based monomer having an aromatic ring to structural units derived from all monomers of the vinyl-based polymer is preferably 5% to 80%, more preferably 10% to 70%, and still more preferably 25% to 60%. In a case of being within the above-described range, the cured product of the curable composition containing the vinyl-based polymer has improved water resistance and strength.

A mass proportion of a structure derived from a (meth)acrylic monomer (3- to 20-mer of a (meth)acrylic monomer) in the terminal structure to structural units derived from all monomers of the vinyl-based polymer according to the present invention is preferably 1 ppm to 10%, more preferably 100 ppm to 7%, and still more preferably 2,000 ppm to 4%. In a case of being the above-described lower limit value or more, the solvent solubility of the curable composition containing the vinyl-based polymer tends to be improved. In a case of being the above-described upper limit value or less, purity of the vinyl-based polymer is improved.

A mass proportion of the structural unit derived from other monomers having a polymerizable double bond to structural units derived from all monomers of the vinyl-based polymer according to the present invention is preferably 0% to 90%, more preferably 5% to 80%, and still more preferably 10% to 70%. In a case of being within the above-described range, compatibility between the vinyl-based polymer and all monomers in a case of forming the curable composition is improved.

The mass proportion of the structure derived from a (meth)acrylic monomer (3-to 20-mer of a (meth)acrylic monomer) in the terminal structure to the structural units derived from all monomers of the vinyl-based polymer can be obtained from a mass percentage calculated from a mass ratio of each monomer used in the polymerization raw material and the 3- to 20-mer of a (meth)acrylic monomer.

An acid value of the vinyl-based polymer according to the present invention is 35 to 300 mgKOH/g, preferably 60 to 300 mgKOH/g, more preferably 70 to 240 mgKOH/g, and still more preferably 120 to 200 mgKOH/g. In a case of being the above-described lower limit value or more, the solubility of the vinyl-based polymer in alkaline water is improved. In a case of being the above-described upper limit value or less, the water resistance of the cured product of the curable composition containing the vinyl-based polymer is improved.

The acid value of the vinyl-based polymer can be obtained by setting a color change point of phenolphthalein as a basis, dissolving the polymer in a toluene-ethanol 1:1 solution, titrating the mixture with a dropwise addition of KOH dissolved in ethanol, and measuring the number of mg of KOH required to neutralize 1 g of the polymer.

The vinyl-based polymer according to the present invention may be used in a state of being neutralized. As a base which can be used for neutralizing the vinyl-based polymer according to the present invention, for example, metal hydroxide, ammonia, and an amine compound are exemplary examples.

As the metal hydroxide, for example, lithium hydroxide, sodium hydroxide, and potassium hydroxide are exemplary examples.

As the amine compound, for example, morpholine, thiomorpholine, triethylamine, propylamine, diethylamine, tripropylamine, dibutylamine, amylamine, 1-aminooctane, 2-dimethylaminoethanol, ethylaminoethanol, 2-diethylaminoethanol, 1-amino-2-propanol, 2-amino-1-propanol, 3-amino-1-propanol, 1-dimethylamino-2-propanol, 3-dimethylamino-1-propanol, 2-propylaminoethanol, ethoxypropylamine, aminobenzyl alcohol, pyrrolidine, and piperidine are exemplary examples.

A weight-average molecular weight of the vinyl-based polymer according to the present invention is preferably 5,000 to 1,000,000, more preferably 5,000 to 200,000, still more preferably 6,000 to 120,000, and particularly preferably 7,000 to 80,000. In a case of being the above-described lower limit value or more, the water resistance and coating film strength of the cured product of the curable composition containing the vinyl-based polymer tend to be improved. In a case of being the above-described upper limit value or less, viscosity of the curable composition containing the vinyl-based polymer can be lowered, and workability tends to be improved.

In the vinyl-based polymer according to the present invention, a ratio (Mw/Mn) of a weight-average molecular weight (Mw) to a number-average molecular weight (Mn) is preferably 1.0 to 5.0 and more preferably 1.0 to 3.5. In a case where Mw/Mn is within the above-described range, viscosity of the curable composition containing the vinyl-based polymer can be lowered, and workability is further improved. In addition, resolution is improved when the cured product of the curable composition is developed.

The weight-average molecular weight (Mw) and the number-average molecular weight (Mn) can be measured by gel permeation chromatography (GPC) with a conversion using a standard polystyrene calibration curve.

Measurement conditions of GPC are as follows.
Apparatus: Tosoh HLC-8220GPC (manufactured by Tosoh Corporation)
Column: Tosoh TSKgel G5000HXL * GMHXL-L (7.8 mmφ x 300 mm)
Eluent: tetrahydrofuran
Sample concentration: 0.4% by weight
Measurement temperature: 40° C.
Injection volume: 100 µL
Flow rate: 1.0 mL/min
Detector: RI (built-in equipment) and UV (Tosoh UV-8220)

The vinyl-based polymer according to the present invention may be, for example, particulate, block, or solution. From the viewpoint that it is easy to handle the vinyl-based polymer when dissolved in a solvent or alkaline water, it is preferable to be particulate.

In a case where the vinyl-based polymer is particulate, a mass-average particle size of the particulate vinyl-based polymer is preferably 20 to 2,000 µm, more preferably 50 to 800 µm, and still more preferably 100 to 600 µm. In a case of being the above-described lower limit value or more, a risk of dust explosion is suppressed, and blending work is easier. In a case of being the above-described upper limit value or less, the solvent solubility of the polymer is improved, and the dissolution time in the solvent is shortened.

The mass-average particle size can be calculated by shaking 20 g of a granular resin for 5 minutes and classifying it using a standard sieve.

In a case where the shape of the vinyl-based polymer is particulate or block, a moisture content of the vinyl-based polymer is preferably 0.1% to 5.0% by weight and more preferably 0.5% to 4.5% by weight. In a case of being within the above-described range, handleability of the polymer when obtaining the polymer is improved.

The moisture content can be calculated by setting a moisture content in a case where the vinyl-based polymer is dried at 105° C. for 2 hours to 0%, and measuring a drying loss of the weight of the vinyl-based polymer before and after drying when dried at 105° C. for 2 hours.

### Method for Producing Vinyl-Based Polymer

The vinyl-based polymer according to the present invention can be produced by a commonly known polymerization method such as bulk polymerization, solution polymerization, and suspension polymerization. From the viewpoint of obtaining a particulate polymer which is easy to handle, the suspension polymerization is preferable.

For example, the vinyl-based polymer according to the present invention can be produced by a method including a polymerization step using a suspension polymerization method, a first dehydration step, a washing step, a second dehydration step, and a drying step.

### (Polymerization Step)

The polymerization step is a step of obtaining a vinyl-based polymer by a suspension polymerization of the vinyl-based monomer having an acid group, the vinyl-based monomer having an aromatic ring, and the other monomers having a polymerizable double bond as necessary.

A known method can be adopted as the suspension polymerization method, and for example, a method in which the vinyl-based monomer having an acid group, the vinyl-based monomer having an aromatic ring, and the other monomers having a polymerizable double bond as necessary are polymerized in water in a container having a polymerization temperature control function and a stirring function, in the presence of a polymerization aid, is an exemplary example.

As the polymerization aid, a polymerization initiator, a chain transfer agent, a dispersant, and a dispersion aid are exemplary examples.

As the polymerization initiator, for example, 2,2′-azobisisobutyronitrile, 2,2′-azobis(2-methylbutyronitrile), benzoyl peroxide, and lauroyl peroxide are exemplary examples.

As the chain transfer agent, one or more of 3- to 20-mer of a (meth)acrylic monomer are used. The one or more of 3- to 20-mer of a (meth)acrylic monomer may be used in combination with t-dodecyl mercaptan, n-dodecyl mercaptan, octylthioglycolate, or α-methylstyrene dimer.

As the dispersant, for example, a surfactant which stably disperses the monomers in water, and specifically, a copolymer of 2-sulfoethylsodium methacrylate, potassium methacrylate, and methyl methacrylate, a copolymer of 3-sodium sulfopropyl methacrylate and methyl methacrylate, a copolymer of sodium methacrylate and methacrylic acid, polyvinyl alcohol, polyvinylpyrrolidone, hydroxyethylcellulose, and hydroxypropylcellulose are exemplary examples.

As the dispersion aid, for example, sodium sulfate, sodium carbonate, sodium dihydrogen phosphate, disodium hydrogen phosphate, potassium chloride, calcium acetate, magnesium sulfate, and manganese sulfate are exemplary examples.

The vinyl-based polymer obtained by the suspension polymerization is obtained in a slurry state. By dehydrating the slurry, vinyl-based polymer particles which are nearly spherical are obtained.

### (Dehydration Step)

As the dehydration step, a first dehydration step in which the slurry after the suspension polymerization is dehydrated with a dehydrator or the like to separate the vinyl-based polymer particles from the reaction liquid, and a second dehydration step in which vinyl-based polymer particles after the washing step are dehydrated with a dehydrator or the like to separate the vinyl-based polymer particles from the washing liquid are exemplary examples. Various types of the dehydrator can be used in each dehydration step, and for example, a centrifugal dehydrator, a mechanism for removing water by suction on a perforated belt, or the like can be appropriately selected and used. One dehydrator may be used, two of the same model of the dehydrators may be prepared and used in each dehydration step, or a plurality of different dehydrator models may be used. It is possible to appropriately select a model which meets the purpose in terms of product quality, equipment investment cost, productivity, operating cost, and the like. When emphasizing the balance between the product quality and the production speed, it is preferable to use a dedicated dehydrator in each dehydration step.

### (Washing Step)

The washing step increases purity of the vinyl-based polymer.

As the washing method, for example, a method of adding a washing liquid to the vinyl-based polymer particles dehydrated in the first dehydration step to re-slurry the vinyl-based polymer, and stirring and mixing the slurry, and a method in which the dehydration step is performed in a dehydrator with a washing function, and a washing liquid is added to the vinyl-based polymer are exemplary examples. A combination of these washing methods may be used for the washing.

The type and amount of the washing liquid may be selected so that the purpose of the washing step is achieved. As a washing liquid, for example, water (ion-exchanged water, distilled water, purified water, and the like), an aqueous solution in which a sodium salt is dissolved, and methanol are exemplary examples.

### (Drying Step)

The drying step is a step of drying the vinyl-based polymer particles after the second dehydration step.

Water remains on the surface of the vinyl-based polymer particles after the second dehydration step. In addition, the interior of the vinyl-based polymer is in a state close to saturated water absorption. Therefore, it is preferable to perform drying in order to further reduce the moisture content of the vinyl-based polymer.

Various dries can be used for the drying, and for example, a dryer which dries the vinyl-based polymer particles by heating under reduced pressure, a dryer which simultaneously dries the vinyl-based polymer particles while air-flying the vinyl-based polymer particles in pipes using heated air, a dryer which dries the vinyl-based polymer particles while blowing heated air from the lower side of a perforated plate to flow the vinyl polymer particles on the upper side, and the like are exemplary examples.

It is preferable that the drying step is performed so that the moisture content of the vinyl-based polymer after the drying step is 0.1% to 5.0% by weight.

The chemical structure of the obtained vinyl-based polymer can be confirmed by a known analytical method using ¹H-NMR, ¹³C-NMR, or the like.

### Effect

The vinyl-based polymer according to the present invention has favorable solubility in various solvents and alkaline water and has low odor, so that it is excellent in workability. The curable composition containing the vinyl-based polymer according to the present invention is excellent in uniformity of formulation, and thus lumps and cloudiness are less likely to occur.

### Application

The vinyl-based polymer according to the present invention can be used, for example, as a raw material for inks, paints, binders for baking ceramic, adhesives, and dry film resists. In particular, the vinyl-based polymer according to the present invention is suitable as a raw material for dry film resists.

### Curable Composition

The curable composition according to the present invention contains the vinyl-based polymer according to the present invention and a compound having a polymerizable double bond. Optional components may be contained as necessary.

From the viewpoint of improving curability of the curable composition, it is preferable that the curable composition according to the present invention further contains one or more of 3- to 20-mer of a (meth)acrylic monomer.

From the viewpoint of improving the curability of the curable composition, the 3- to 20-mer of a (meth)acrylic monomer is more preferably 3- to 10-mer of a (meth)acrylic monomer, and still more preferably 3- to 5-mer of a (meth)acrylic monomer.

As the compound having a polymerizable double bond, for example, the 3- to 20-mer of a (meth)acrylic monomer, a monomer which can be used in the production of the vinyl-based polymer described above, 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, neopentyl glycol di(meth)acrylate hydroxypivalate, dicyclopentadienyl di(meth)acrylate, caprolactone-modified dicyclopentadienyl di(meth)acrylate, allylated cyclohexyl di(meth)acrylate, isocyanurate di(meth)acrylate, trimethylolpropane tri(meth)acrylate, dipentaerythritol tri(meth)acrylate, pentaerythritol tri(meth)acrylate, methyltrimethyl tri(meth)acrylate, tris(acryloxyethyl)isocyanurate, dipentaerythritol penta(meth)acrylate, and dipentaerythritol hexa(meth)acrylate are exemplary examples. From the balance between curability and peelability, a monomer which can be used in the production of the vinyl-based polymer described above, 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, neopentyl glycol di(meth)acrylate hydroxypivalate, dicyclopentadienyl di(meth)acrylate, caprolactone-modified dicyclopentadienyl di(meth)acrylate, allylated cyclohexyl di(meth)acrylate, or isocyanurate di(meth)acrylate is preferable.

As the optional components, various known additives are exemplary examples. As the various additives, for example, a solvent, a photopolymerization initiator, a dye, and a stabilizer are exemplary examples.

Various known additives can be appropriately selected depending on the desired physical characteristics and properties of the curable composition.

For example, the curable composition according to the present invention can be produced by a method in which the vinyl-based polymer according to the present invention, the compound having a polymerizable double bond, and the optional components as necessary are mixed in a conventional stirrer.

The curable composition according to the present invention can be used, for example, for semiconductor manufacturing resists, dry film resists, and solder resists.

In a case where the curable composition according to the present invention is used for a dry film resist, a composition in which the vinyl-based polymer according to the present invention, a compound having a polymerizable double bond, a solvent, a photopolymerization initiator, and optional components as necessary are mixed is preferable.

As the compound having a polymerizable double bond, for example, the compound having a polymerizable double bond, which can be used in the above-described curable composition, is an exemplary example.

From the balance of curability and coatability, a content of the compound having a polymerizable double bond in the curable composition is preferably 5 to 90 parts by mass with respect to 100 parts by mass of the total amount of the vinyl-based polymer according to the present invention.

The solvent is not particularly limited and can be appropriately selected depending on the purpose, and for example, propylene glycol monomethyl ether, acetone, methyl ethyl ketone, methyl isobutyl ketone, toluene, xylene, methanol, ethanol, isopropyl alcohol, ethyl acetate, and an aqueous solution of a base which can be used for neutralizing the vinyl-based polymer according to the present invention, when the solvent is used for neutralizing the vinyl-based polymer according to the present invention, are exemplary examples.

These solvents may be used alone or in combination of two or more thereof.

As the photopolymerization initiator, for example, benzoin, benzoin alkyl ether, ketals, acetophenones, benzophenone, 4,4′-dimethyl-amino-benzophenone, 4,4′-diethyl-amino-benzophenone, thioxanthenones, morpholino-propanone compounds, 2,4,5-triarylimidazole dimer, 2,2′-bis(2-chlorophenyl)-4,4’,5,5′-tetraphenyl-1,2′-biimidazole, oxime esters, and thioxanthones can be exemplary examples.

These photopolymerization initiators may be used alone or in combination of two or more thereof.

A content of the photopolymerization initiator in the curable composition is preferably 0.01 parts by mass or more and 1 part by mass or less with respect to 100 parts by mass of the total amount of the compound having a polymerizable double bond.

As the stabilizer, for example, p-methoxyphenol, hydroquinone, pyrogallol, naphthylamine, and t-methylcatechol are exemplary examples.

As the dye, for example, malachite green, victoria pure blue, brilliant green, methyl violet, leucocrystal violet, diphenylamine, and benzylamine can be exemplary examples.

In addition, an antifoaming agent or a leveling agent can be used as the optional components.

### Cured Product of Curable Composition

A photosensitive element can be formed by, for example, applying the curable composition onto a polymer film such as polyesters, for example, polyethylene terephthalate, polyethylenes, and polypropylenes as a support such that a thickness after drying is 1 µm to 100 µm, and removing volatile components. A cured product of the curable composition is obtained by exposing the photosensitive element to ultraviolet light having a wavelength range of 250 nm to 420 nm, thereby forming a circuit pattern.

### EXAMPLES

Hereinafter, the present invention will be described in more detail with reference to Examples, but the present invention is not limited to these.

In the description below, “parts” means parts by mass. In Examples and Comparative Examples, each vinyl-based polymer was synthesized according to the raw material formulation ratio shown in Table 1. A dispersant used in Examples and Comparative Examples was produced by a method described later.

Measurement and evaluation of each physical property in Examples and Comparative Examples were carried out by the following methods.

### Measurement and Evaluation

### <Evaluation of Solvent Solubility of Vinyl-Based Polymer Particles>

70 g of propylene glycol monomethyl ether as a solvent was charged into a flask, and 30 g of vinyl-based polymer particles were added thereto little by little while stirring with a stirrer at room temperature. After stirring at 50° C. for 2 hours, the solution was cooled to room temperature, and the solubility was visually confirmed based on transparency of the solution, and evaluated according to the following evaluation standard.

### (Evaluation Standard of Solvent Solubility)

A: the solution was transparent, and the solubility was very excellent.

B: although the dissolution was completed over 2 hours or more, the solution was transparent, and the solubility was excellent.

C: the solution was slightly cloudy, and the solubility was inferior.

D: the solution was cloudy, and the solubility was poor.

### <Evaluation of Alkaline Water Solubility of Vinyl-Based Polymer Particles>

50 mL of a 0.5 M potassium hydroxide aqueous solution was charged into a flask, and 5 g of vinyl-based polymer particles were added thereto little by little while stirring with a stirrer at room temperature. After stirring at 50° C. for 2 hours and cooling to room temperature, solubility of the vinyl-based polymer particles was visually observed for the presence or absence of undissolved vinyl-based polymer particles, and turbidity was measured with a turbidity meter (manufactured by EUTECH, portable turbidity meter TN100IR) and evaluated according to the following evaluation standard.

### (Evaluation Standard of Alkaline Water Solubility)

A: the turbidity of the potassium hydroxide aqueous solution after dissolving the vinyl-based polymer particles was less than 15 NTU.

B: the turbidity of the potassium hydroxide aqueous solution after dissolving the vinyl-based polymer particles was 15 NTU or more.

C: undissolved vinyl-based polymer particles remained, and the solubility was poor.

### <Measurement of Moisture Content of Vinyl-Based Polymer Particles>

A moisture content in a case where the vinyl-based polymer particles were dried at 105° C. for 2 hours was set to 0%, and a moisture content was calculated from a drying loss of a mass of the vinyl-based polymer before and after the drying.

### <Evaluation of Odor>

A coating solution obtained by dissolving vinyl-based polymer/acetone/ethylene oxide-modified bisphenol A diacrylate in a mass ratio of 30/45/25 was applied onto a PET film (manufactured by Mitsubishi Chemical Corporation., DIAFOIL R310-16, made of polyethylene terephthalate) using an applicator. Thereafter, after drying at room temperature for 5 minutes, the coating film was placed in a dryer at 40° C. for 15 minutes. Furthermore, the coating film was pressure-bonded to a copper plate with a laminator (upper and lower roll temperature: 100° C., roll speed: 1 m/min, pressure setting: 0.3 MPa), and cooled to room temperature. Thereafter, odor when the PET film was peeled off was sensory evaluated by 7 panelists according to the following evaluation standard of odor, and the maximum number of people was taken as the evaluation result of the odor.

### Evaluation Standard of Odor

A: no unpleasant odor at all
B: slightly unpleasant odor
C: strongly unpleasant odor

### Production of Dispersant (1)

In a polymerization apparatus equipped with a stirrer, a condenser, and a thermometer, 1230 g of deionized water, 60 g of 2-sulfoethylsodium methacrylate, 10 g of potassium methacrylate, and 12 g of methyl methacrylate were charged and stirred, and while replacing the inside of the polymerization apparatus with nitrogen, the temperature was raised to a polymerization temperature of 50° C. Thereafter, 0.08 g of 2,2′-azobis(2-methylpropionamidine) dihydrochloride as a polymerization initiator was added thereto, and the temperature was raised to a polymerization temperature of 60° C. Simultaneously with the addition of the polymerization initiator, using a dropping pump, methyl methacrylate was continuously added dropwise thereto at a rate of 0.24 g/min for 75 minutes, and the temperature was maintained at the polymerization temperature of 60° C. for 6 hours and then lowered to room temperature, thereby obtaining a dispersant (1). A solid content of the dispersant (1) was 7.5% by weight.

### Production Example 1 Production of MMA Trimmer

0.114 mmol of cobalt (11) acetate tetrahydrate and 0.228 mmol of dimethylglyoxime with respect to 1 mol of a monomer were charged into a flask with a cooling tube, and 0.01 mol of pyridine and 166 ml of methyl ethyl ketone (MEK) were added thereto using a syringe. The obtained mixture was freeze-degassed three times under a nitrogen stream, and then heated and stirred at 80° C. for 30 minutes to obtain a catalyst mixed solution. Separately, 1 mol of a methyl methacrylate (MMA) solution with a 1% by weight of AIBN was freeze-degassed three times under a nitrogen stream to prepare an AIBN mixed solution, and the catalyst mixed solution was added dropwise to the AIBN mixed solution over 5 hours while maintaining the temperature at 80° C. After the dropwise addition was completed, the temperature was further maintained at 80° C. for 1 hour to obtain a polymerization mixed solution. The obtained polymerization mixed solution was cooled to room temperature, and MEK was removed by an evaporator. The residue was dissolved in toluene and subjected to silica gel column chromatography using toluene as an eluent to obtain a MMA trimer. Purity was confirmed by ¹H-NMR.

### Production Example 2 Production of MMA Dimer to Tridecamer

The polymerization mixed solution obtained in Production Example 1 was cooled to room temperature, MEK was removed by an evaporator, and purity was confirmed by ¹H-NMR.

### Production Example 3 Production of MMA Octamer

The polymerization mixed solution obtained in Production Example 1 was cooled to room temperature, and MEK was removed by an evaporator. The residue was dissolved in toluene and subjected to silica gel column chromatography using toluene as an eluent to obtain a MMA octamer. Purity was confirmed by ¹H-NMR.

### Production Example 4 Production of BMA Trimmer

A BMA trimer was obtained in the same formulation as in Production Example 1, except that n-butyl methacrylate (BMA) was used as the monomer. Purity was confirmed by ¹H-NMR.

### Example 1

In a polymerization apparatus equipped with a stirrer, a condenser, and a thermometer, a monomer mixture in which 60 parts by mass of styrene, 10 parts by mass of methyl methacrylate, and 30 parts by mass of methacrylic acid were uniformly dissolved; 0.25 parts by mass of 2,2′-azobis(2-methylbutyronitrile) as a polymerization initiator; 4 parts by mass of the MMA trimer as a chain transfer agent; and 200 parts by mass of pure water in which 0.8 parts by mass of the dispersant (1) and 0.3 parts by mass of sodium sulfate as a dispersion aid were uniformly dissolved were charged and replaced with nitrogen while stirring. Thereafter, suspension polymerization was started at 75° C., and after detecting a peak of polymerization exotherm, the polymerization was further carried out at 85° C. for 30 minutes (polymerization step).

After the polymerization, the interior of the kettle was cooled to room temperature, and the produced slurry was dehydrated with a centrifugal dehydrator (first dehydration step).

The obtained vinyl-based polymer and pure water as a washing liquid were put into a washing tank such that a mass ratio (vinyl-based polymer particles:washing liquid) was 1:2, and stirred and mixed for 20 minutes for washing (washing step). Thereafter, the resultant was dehydrated with a centrifugal dehydrator (second dehydration step).

After the dehydration, the dehydrated vinyl-based polymer particles were put into a fluidized tank dryer in which the internal temperature was set to 50° C., and dried to a moisture content of 5% or less (drying step).

Solvent solubility and alkaline water solubility were evaluated for the obtained powdery vinyl-based polymer particles.

The results are shown in Table 1.

### Examples 2 to 23 and Comparative Examples 1 to 3

Powdery vinyl-based polymers were produced in the same manner as in Example 1, except that the raw material formulation ratio was set as shown in Tables 1 to 3, and the various measurements and evaluations were performed.

The results are shown in Tables 1 to 3.

TABLE 1

| | | Example | | | | | | | | |
|---|---|---|---|---|---|---|---|---|---|---|
| | | 1 | 2 | 3 | 4 | 5 | 6 | 7 | 8 | 9 |
| Vinyl-based monomer having aromatic ring [part] | St | 60 | 60 | 60 | 60 | 60 | 60 | 60 | 50 | 25 |
| | BzMA | | | | | | | | | |
| Other monomers having polymerizable double bond [part] | MMA | 10 | 10 | 10 | 10 | 10 | 10 | 10 | 10 | 45 |
| | BA | | | | | | | | | |
| | iBMA | | | | | | | | | |
| Vinyl-based monomer having acid group [part] | MAA | 30 | 30 | 30 | 30 | 30 | 30 | 30 | 40 | 30 |
| Chain transfer agent [part] | tDM | | | 0.1 | | | | | | |
| | nDM | | | | 0.6 | 1.9 | | | | |
| | OTG | | | | | 1.0 | | | | |
| | MMA trimer | 4.0 | 3.0 | 2.5 | 2.0 | 4.0 | 1.0 | 10.0 | 3.0 | 3.0 |
| | MMA dimer to tridecamer | | | | | | | | | |
| | MMA octamer | | | | | | | | | |
| | BMA trimer | | | | | | | | | |
| Acid value [mgKOH/g] | | 186 | 187 | 187 | 185 | 180 | 190 | 176 | 240 | 185 |
| Molecular weight | Mw | 45000 | 55000 | 62000 | 49000 | 24000 | 101000 | 20000 | 58000 | 40000 |
| | Mw/Mn | 2.4 | 2.5 | 2.5 | 2.9 | 3.7 | 2.5 | 2.2 | 2.4 | 2.3 |
| Evaluation result | Solvent solubility | A | A | A | A | A | A | A | A | A |
| | Alkaline water solubility | A | A | A | A | A | A | A | A | A |
| | Odor | A | A | B | B | B | A | A | A | A |

TABLE 2

| | | Example | | | | | | | | |
|---|---|---|---|---|---|---|---|---|---|---|
| | | 10 | 11 | 12 | 13 | 14 | 15 | 16 | 17 | 18 |
| Vinyl-based monomer having aromatic ring [part] | St | 10 | 70 | 60 | 50 | | | | 5 | 5 |
| | BzMA | | | 10 | 10 | | | | | |
| Other monomers having polymerizable double bond [part] | MMA | 70 | 10 | | 10 | 70 | 70 | 40 | 70 | 75 |
| | BA | | | | | | | 30 | 10 | 10 |
| | iBMA | | | | | | | | | |
| Vinyl-based monomer having acid group [part] | MAA | 20 | 20 | 30 | 30 | 30 | 30 | 30 | 15 | 10 |
| Chain transfer agent [part] | tDM | | | | | | | | | |
| | nDM | | | | | | 1.7 | | 2.5 | 2.5 |
| | OTG | | | | | | | | | |
| | MMA trimer | 3.0 | 3.0 | 3.0 | 3.0 | 3.0 | 0.3 | 3.0 | 3.0 | 3.0 |
| | MMA dimer to tridecamer | | | | | | | | | |
| | MMA octamer | | | | | | | | | |
| | BMA trimer | | | | | | | | | |
| Acid value [mgKOH/g] | | 123 | 124 | 184 | 183 | 183 | 185 | 185 | 92 | 64 |
| Molecular weight | Mw | 42000 | 78000 | 56000 | 49000 | 51000 | 23000 | 51000 | 11000 | 11000 |
| | Mw/Mn | 2.3 | 2.8 | 2.5 | 2.4 | 2.6 | 2.1 | 2.7 | 2.0 | 1.9 |
| Evaluation result | Solvent solubility | A | A | A | A | A | A | A | A | A |
| | Alkaline water solubility | A | B | A | A | A | A | A | A | A |
| | Odor | A | A | A | A | A | B | A | B | B |

TABLE 3

| | | Example | | | | | Comparative Example | | |
|---|---|---|---|---|---|---|---|---|---|
| | | 19 | 20 | 21 | 22 | 23 | 1 | 2 | 3 |
| Vinyl-based monomer having aromatic ring [part] | St | 5 | | 60 | 60 | 60 | 60 | | |
| | BzMA | | 5 | | | | | | |
| Other monomers having polymerizable double bond [part] | MMA | 77 | 75 | 10 | 10 | 10 | 10 | 100 | |
| | BA | 10 | 10 | | | | | | |
| | iBMA | | | | | | | | 100 |
| Vinyl-based monomer having acid group [part] | MAA | 8 | 10 | 30 | 30 | 30 | 30 | | |
| Chain transfer agent [part] | tDM | | | | | | 1.9 | | |
| | nDM | 2.5 | 2.5 | | | | | | |
| | OTG | | | | | | | | |
| | MMA trimer | 4.0 | 3.0 | | | | | 3.0 | 1.0 |
| | MMA dimer to tridecamer | | | 3.0 | | | | | |
| | MMA octamer | | | | 8.0 | | | | |
| | BMA trimer | | | | | 4.3 | | | |
| Acid value [mgKOH/g] | | 49 | 63 | 185 | 179 | 188 | 187 | 0 | 0 |
| Molecular weight | Mw | 11000 | 12000 | 56000 | 57000 | 58000 | 20000 | 49000 | 108000 |
| | Mw/Mn | 1.9 | 2.0 | 2.4 | 2.3 | 2.3 | 2.0 | 2.2 | 3.2 |
| Evaluation result | Solvent solubility | A | A | A | A | A | A | B | A |
| | Alkaline water solubility | B | A | A | A | A | A | C | C |
| | Odor | B | B | A | A | A | C | A | A |

Abbreviations used in Tables 1 to 3 are as follows.
St: styrene
MAA: methacrylic acid
MMA: methyl methacrylate
BzMA: benzyl methacrylate
BA: n-butyl acrylate
iBMA: i-butyl methacrylate
PGM: propylene glycol monomethyl ether
tDM: t-dodecyl mercaptan
nDM: n-dodecyl mercaptan
OTG: 2-ethylhexyl thioglycolate
MMA trimer (MMA dimer:MMA trimer:MMA tetramer:MMA pentamer = 1.9:97.1:0.7:0.3 (mass ratio))
MMA octamer (MMA hexamer:MMA heptamer:MMA octamer:MMA nonamer = 0.5:17.1:70.5:11.9 (mass ratio))
MMA dimer to tridecamer (MMA dimer:MMA trimer:MMA tetramer:MMA pentamer:MMA hexamer:MMA heptamer:MMA octamer:MMA nonamer: MMA decamer:MMA undecamer:MMA dodecamer:MMA tridecamer = 1.9:95.2:0.7:0.4:0.5:0.3:0.1:0.1:0.3:0.2:0.2:0.1 (mass ratio))
BMA trimer (BMA dimer:BMA trimer:BMA tetramer = 15.9:83.8:0.3 (mass ratio))

As is clear from the results in Tables 1 to 3, the vinyl-based polymers obtained in Examples 1 to 23 were excellent in solvent solubility and alkaline water solubility, and had low odor.

In the vinyl-based polymer obtained in Comparative Example 1, since the vinyl-based polymer did not have, as the terminal structure of the polymer, the structure derived from one or more of 3- to 20-mer of a (meth)acrylic monomer, the vinyl-based polymer had a strong unpleasant odor.

In the vinyl-based polymers obtained in Comparative Examples 2 and 3, since the acid value was outside the range specified in the present application, the solubility in alkaline water was poor.

### Example 24 and Comparative Examples 2 and 3

Vinyl-based polymers (a) and (z), a compound (b) having a polymerizable double bond, a photopolymerization initiator (c), and a dye (d) were dissolved in an organic solvent (e) with the formulation shown in Table 4 to prepare a coating solution which is a curable composition.

Blending suitability was evaluated according to the following evaluation standard.

### Evaluation Standard of Blending Suitability

A: no cloudiness or lumps was observed in the coating solution, which is favorable.

B: the coating solution was slightly cloudy.

C: the coating solution was strongly cloudy, and undissolved component remained.

The obtained coating solution was applied onto a PET film (manufactured by Mitsubishi Chemical Corporation., DIAFOIL R310-16, made of polyethylene terephthalate) having a thickness of 20 µm using an applicator. After the PET film coated with the coating solution was left at room temperature for 30 minutes, the PET film was dried in a drier at 50° C. for 30 minutes to form a photosensitive layer of 30 µm and obtain a photosensitive film. The photosensitive film was heat-laminated on a copper-clad laminate so that the PET film was on the outside to obtain a test panel. The lamination conditions were set to a roll temperature of 100° C., a roll speed of 1 m/min, and a pressure of 0.3 MPa.

A photomask having a predetermined shape was brought into close contact with the photosensitive film of the test panel, and exposure was performed on the test panel with a parallel exposure machine using a high-pressure mercury lamp as a light source. The exposure energy amount was 30 mJ/cm². After the exposure, the PET film was peeled off, and the film was developed using a sodium carbonate aqueous solution developer having a concentration of 1% by mass to dissolve and remove unexposed portions, thereby obtaining a circuit pattern including a cured product of the curable composition. The development was performed at a developer temperature of 30° C. by spraying the developer.

Resolution and developability were evaluated according to the following evaluation standard.

### Evaluation Standard of Resolution

A: when, using a photomask with a line width (L)/space width (S) (hereinafter, abbreviated as L/S) of 30 µm/30 µm, the film was developed for 1.5 times the minimum time required for developing the unexposed portions, the circuit pattern remained.

B: when, using a photomask with L/S of 30 µm/30 µm, the film was developed for 1.5 times the minimum time required for developing the unexposed portions, the circuit pattern did not remain.

C: since the cured product was insoluble in alkaline water, the development could not be performed, so that the evaluation was not possible.

### Evaluation Standard of Developability

A: the minimum time required for developing the unexposed portions was less than 60 seconds.

B: the minimum time required for developing the unexposed portions was 60 seconds or more.

C: since the cured product was insoluble in alkaline water, the development could not be performed, so that the evaluation was not possible.

TABLE 4

| | | Example | Comparative Example | |
|---|---|---|---|---|
| | | 24 | 4 | 5 |
| Vinyl-based monomer [part] | (a)-1 | 30 | | |
| | (z)-1 | | 30 | |
| | (z)-2 | | | 30 |
| Compound having polymerizable double bond [part] | (b)-1 | 20 | 20 | 20 |
| | (b)-2 | 5 | 5 | 5 |
| Photopolymerization initiator [part] | (c)-1 | 1.5 | 1.5 | 1.5 |
| | (c)-2 | 0.05 | 0.05 | 0.05 |
| Dye [part] | (d)-1 | 0.005 | 0.005 | 0.005 |
| | (d)-2 | 0.5 | 0.5 | 0.5 |
| Solvent [part] | (e)-1 | 80 | 80 | 80 |
| | (e)-2 | 20 | 20 | 20 |
| Evaluation result | Blending suitability | A | A | A |
| | Resolution | A | C | C |
| | Developability | A | C | C |

Abbreviations used in Table 4 are as follows.
(a)-1: vinyl-based polymer obtained in Example 2
(z)-1: vinyl-based polymer obtained in Comparative Example 2
(z)-2: vinyl-based polymer obtained in Comparative Example 3
(b)-1: bisphenol A dimethacrylate (manufactured by SHIN-NAKAMURA CHEMICAL CO, LTD., product name: NK ESTER BPE500) to which 10 mol of ethylene oxide was added
(b)-2: trimethylolpropane EO-modified triacrylate (Toyo Chemicals Co., Ltd., product name: Miramer M3130)
(c)-1: 2,2′-bis(2-chlorophenyl)-4,4’,5,5′-tetraphenyl-1,2′-biimidazole
(c)-2: 4,4′-bis(diethylamino)benzophenone
(d)-1: leucocrystal violet
(d)-2: malachite green
(e)-1: methyl ethyl ketone
(e)-2: methanol

As is clear from the results in Table 4, Example 24 had favorable blending suitability, resolution, and developability.

In Comparative Examples 2 and 3, since the cured product was insoluble in alkaline water, the development could not be performed, so that the resolution and developability could not be evaluated.

### Industrial Applicability

According to the present invention, it is possible to provide a low-odor polymer which can be used in a curable composition and a cured product thereof and is soluble in a solvent, with which a work environment load can be reduced.

1. A vinyl-based polymer comprising:
a terminal structure derived from one or more of 3- to 20-mer of a (meth)acrylic monomer,
wherein an acid value is 35 to 300 mgKOH/g.

2. The vinyl-based polymer according to claim 1,
wherein the terminal structure is a terminal structure derived from a chain transfer agent.

3. The vinyl-based polymer according to claim 1, further comprising:
a structural unit derived from two or more of vinyl-based monomers.

4. The vinyl-based polymer according to claim 3,
wherein one or more of the vinyl-based monomers is a vinyl-based monomer having an acid group.

5. The vinyl-based polymer according to claim 3,
wherein one or more of the vinyl-based monomers is a vinyl-based monomer having an aromatic ring.

6. The vinyl-based polymer according to claim 3,
wherein one or more of the vinyl-based monomers is a (meth)acrylic monomer.

7. The vinyl-based polymer according to claim 6,
wherein the (meth)acrylic monomer in the vinyl-based monomers is (meth)acrylic acid alkyl ester, and
an alkyl group of an ester structure in the (meth)acrylic acid alkyl ester has 1 to 18 carbon atoms.

8. The vinyl-based polymer according to claim 1,
wherein a weight-average molecular weight is 5,000 to 1,000,000.

9. The vinyl-based polymer according to according to claim 1,
wherein the vinyl-based polymer is particulate, and
a mass-average particle size of the particulate vinyl-based polymer is 20 to 2,000 µm.

10. A curable composition comprising:
the vinyl-based polymer according to according to claim 1; and
a compound having a polymerizable double bond.

11. The curable composition according to claim 10, further comprising:
one or more of 3- to 20-mer of a (meth)acrylic monomer.

12. A cured product of the curable composition according to claim 10.
